(19) United States
(12) Patent Application Publication
(10) Pub. No.: US 2015/0053663 A1
(43) Pub. Date: Feb. 26, 2015

(54) PANEL FOR AN AIRCRAFT

(71) Applicant: AIRBUS OPERATIONS LIMITED, Bristol (GB)

(72) Inventors: Nebojsa SAKOTA, Bristol (GB); Andrew MCVEY, Bristol (GB)

(21) Appl. No.: 14/465,235

(22) Filed: Aug. 21, 2014

(30) Foreign Application Priority Data
Aug. 21, 2013 (GB) 1314959.6

(51) Int. Cl. H05K 1/03; H05B 3/00; H05K 1/02; B64C 1/00; H01B 19/04

(52) U.S. Cl. CPC H05K 1/032; B64C 1/00; H01B 19/04; H05K 1/0271; H05B 3/0004
USPC 219/202; 156/51; 174/258

(57) ABSTRACT

A panel for an aircraft is disclosed. The panel has a body with an integral conductor for the transmission of electrical power and/or signals therethrough.

### BACKGROUND TO THE INVENTION

During flight ice commonly forms on surfaces of the wings, fuselage and other parts of an aircraft. Ice forms as a result of the low temperatures and humidity experienced at high altitudes and aircraft typically use a hot air feed from the engines (jet or combustion) to heat key surfaces and prevent ice from forming. For example, on a commercial airliner hot air is bled from the engine and directed to the leading edge of the wings where it heats the surface to prevent ice from accumulating.

However, use of hot air from the engines reduces the fuel efficiency of those engines and also requires various tubes and nozzles to direct the hot air appropriately. Electrically powered heaters have been employed in order to improve fuel efficiency. These electric heaters typically comprise a heater mat comprising a heating element, which is adhered to a surface of the skin of the aircraft, and a cable harness which connects that heater mat to a power source, typically located in the fuselage.

However, space is limited and weight should be minimised and cable harnesses are often bulky and inconvenient for routing to many parts of the aircraft. For example, in the leading edge area of a wing there is limited space available for cable harnesses between the front edges of the spars, the curved profile of the leading edge skin panel and between any other apparatus in that area, such as slats and actuators. Moreover, modern wing design is trending towards thinner wing profiles to reduce drag, which further reduces the space available within wings for cable harnesses, connectors, supporting brackets and any other apparatus.

This issue is further exacerbated by the stringent safety standards for cable harnesses in aircraft. Cables must be well insulated and supported to prevent the cables from sagging or moving around. Any risk of arcing or shorting must be eliminated and any possibility of cables being worn, chafed or rubbed must be accounted for. Therefore, cable harnesses in aircraft are typically large, cumbersome and space consuming. Moreover, strict segregation rules exist in many parts of an aircraft to keep critical systems separated for safety reasons. Therefore, wiring routes are often indirect which adds more complexity and increases the weight of the wiring system.

Electric heater mat systems for de-icing areas of an aircraft, such as those described above, are vulnerable to failure because if only one heater mat or cable were to fail then that area of the aircraft skin would be vulnerable to ice formation. If, for example, ice were to form on an aerodynamic surface, or control surface, then the pilot's control over the aircraft may be affected. Therefore, heater mat systems are provided with independent power supply wires for each heater mat which significantly increases the number of cable harnesses which must be routed through the aircraft.

Aircraft have many other electrical systems that require a great number of wires and cables to be routed across all areas of the aircraft. Therefore, problems similar to those described above may occur in all areas of an aircraft.

### SUMMARY OF THE INVENTION

In accordance with embodiments of the invention, there is provided a panel to form part of an external skin of an aircraft, comprising a body having a plurality of integral conductors for the transmission of electrical power and/or signals through said body to heating elements and/or other apparatus connected to said integral conductors, said integral conductors being embedded in said body and insulated from each other.

A panel having integrated conductors will occupy significantly less space than an equivalent cable harness. Moreover, the panel will provide protection against movements, vibrations and any other wear or sagging that may jeopardise the insulation and integrity of a cable. Furthermore, no supporting brackets or cable glands or other apparatus for securing cables and cable harnesses are required which can reduce the weight of the system and the space it occupies. Also, by embedding conductors in a panel, the segregation requirements may be overcome because the conductors are completely separated from other adjacent systems.

Furthermore, by embedding the conducting elements in the panel the size of the conducting elements can be reduced. This means that the panel with embedded conducting elements will have a lower weight than a panel without embedded conducting elements and a cable harness and associated components. By reducing the weight of the conducting elements, the aircraft as a whole can be made lighter and this improve efficiency.

The body may be formed from a thermoplastic material.

The body may comprise thermoplastic layers and the conductors may then be sandwiched between said thermoplastic layers to form an insulated sheet.

The body may be formed from a fibre reinforced polymer material.

In another embodiment, the body may comprise fibre reinforced polymer layers and the conductors may then be sandwiched between said fibre reinforced polymer layers to form an insulated sheet.

The insulated sheet can be an integral part of the panel. Alternatively, the insulated sheet can be separate to the panel but embedded into the panel during its manufacture.

The panel may further comprise a terminal that is connected to each conductor to facilitate connection of electrical apparatus to each conductor.

The panel may further comprise at least one conductor configured to transmit electrical power to a resistive electric heating element.

As the panel forms a part of the external skin of an aircraft, the embedded conducting elements, will be cooled by the transfer of heat to the cold air moving over the surface of the skin during flight. Therefore, the operating temperature of the conducting elements is reduced, allowing the size of the conducting elements to be reduced. In particular, the lower operating temperature means that the size of the conducting elements can be reduced without causing overheating of the conducting elements. This means that the conducting elements, and therefore the panel and the aircraft, have less weight. Furthermore, cooler electrical conductors have a lower resistance and cause less interference to electrical signals, so the quality of any signals being carried by the conducting elements can be improved.

According to another aspect of the invention, there is also provided a method of manufacturing a panel to form part of an external skin of an aircraft, said panel comprising a body and the method including the step of integrating a plurality of conductors into said body for the transmission of electrical power and/or signals through said body to heating elements and/or other apparatus connected to said integral conductors by embedding said conductors into said body so that they are insulated from each other.

The method may further comprise the step of positioning said conductor between thermoplastic layers to form an insulating sheet and embedding said sheet into the panel during the step of manufacturing the panel.

The method may further comprise the step of integrating said conductor with a fibre reinforced polymer material to form said body.

The fibre reinforced polymer material can form an integral part of the panel and the step of integrating said conductors with a fibre reinforced polymer material may comprise embedding said conductors into said fibre reinforced polymer material during the step of laying up or curing said fibre reinforced polymer material to form the panel.

The method may further comprise the step of bonding or attaching the body to a surface of said panel during manufacture of said panel.

### BRIEF DESCRIPTION OF THE DRAWINGS

Embodiments of the invention will now be described, by way of example only, with reference to the drawings in which:

FIG. 1 shows a sheet with integrated conducting elements;

FIGS. 2a and 2b show cross-sections of sheets with integrated conducting elements;

FIG. 3 shows a sheet with integrated conducting elements and electrical terminals;

FIG. 4 shows a partially exploded view of a part of an aircraft wing, showing the different layers of the wing, one of which includes a sheet of FIGS. 1 to 3;

FIG. 5 shows a cross-section of a part of an aircraft wing having a sheet of FIGS. 1 to 3;

FIG. 6 shows a view of part of an aircraft wing, including a panel;

FIG. 7 shows a view of the inside of part of an aircraft wing, including a panel; and,

FIG. 8 shows a view of the inside of part of an aircraft wing, including a panel and a cable harness electrically connected to the panel.

### DETAILED DESCRIPTION OF THE DRAWINGS

The invention provides a means for integrating wires or cables into a panel which can form a part of the structure of the aircraft. In this way, the wires and cables are kept out of the confined spaces and there is no longer any need for bulky and heavy insulators and brackets for protecting and supporting the cable harnesses. The wires may be embedded within or sandwiched between one or more thermoplastic or composite sheets which are bonded to, attached to, or integrally formed with the structure of the aircraft, for example they may be attached to a skin panel of the aircraft. This creates more free space within the wing, reduces the weight of the electrical system and also simplifies maintenance procedures.

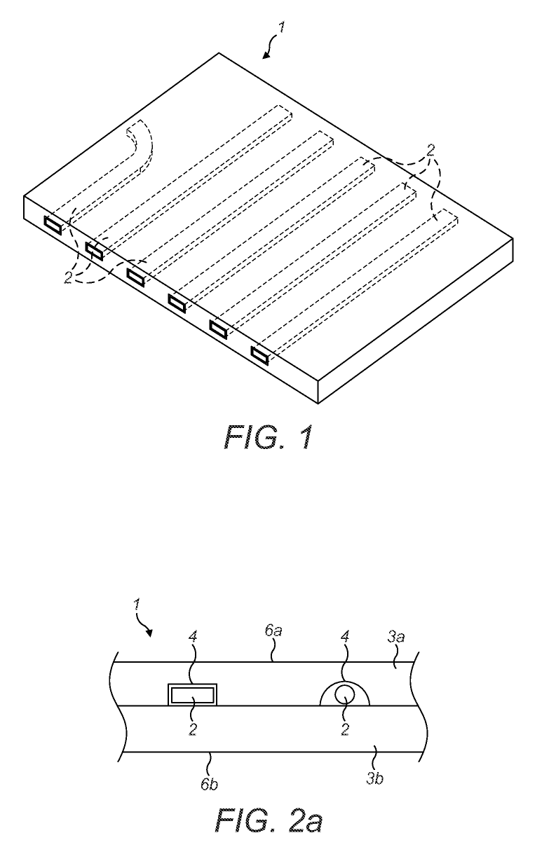

FIG. 1 shows an example of a sheet 1 having conducting elements 2 embedded within the sheet 1. The sheet 1 is flat and rectangular and in this example five conducting elements 2 extend between opposing ends of the sheet 1, while one of the conducting elements turns through 90 degrees and extends towards an adjacent end of the sheet 1. It will be appreciated that the sheet 1 may be made into any shape and may be flat or curved or have any profile. The conducting elements 2 may extend in any direction and configuration through the sheet 1, as required for the particular application.

In one example, conducting elements are embedded in a thermoplastic sheet which is adhered to, attached to, or integrally formed with a surface panel of the aircraft. The conducting elements are embedded in a thermoplastic sheet such that the thermoplastic material insulates the conducting elements from each other and from any nearby objects. The sheet with embedded conducting elements may be produced by an extrusion process or a printing process or a moulding or casting process.

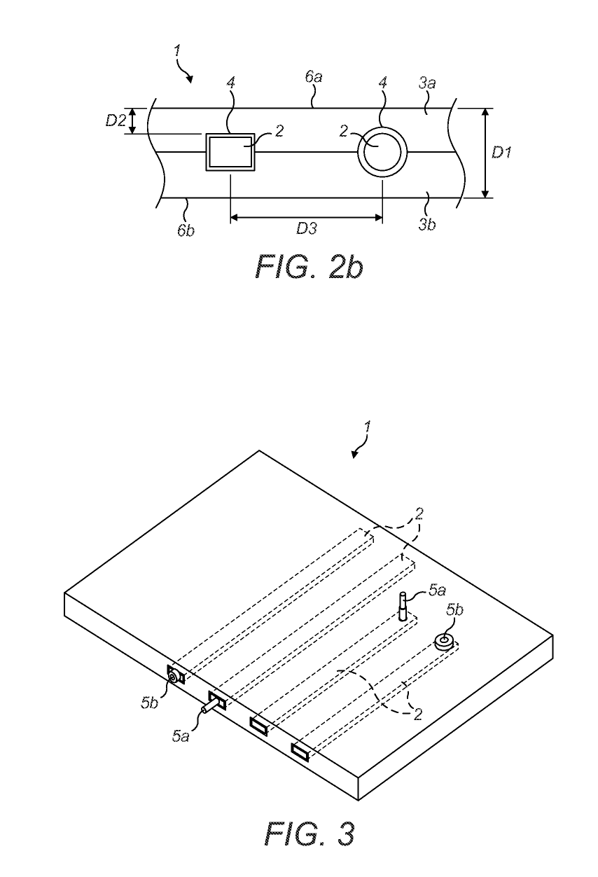

In another example, shown in FIGS. 2a and 2b, conducting elements 2 can be sandwiched between two or more thermoplastic sheets 3a,3b, at least one of which may have a recess 4 to receive the conducting elements 2. These sheets 3a,3b can then be joined together with the conducting elements 2 between them. The sheets 3a,3b may be joined by adhesive or by sonic welding or any other means of joining thermoplastic materials. The conducting elements 2 may be adhered in the recesses 4 or may be push-fitted in the recess(es) 4 in the first sheet 3a, or may simply be placed in the recess(es) 4 and retained by the second thermoplastic sheet 3b. In one example, the conducting elements 2 are retained in the recess(es) 4 in the thermoplastic sheet(s) 3a,3b by a hard-setting resin material, for example a thermoplastic resin such as polyetheretherketone (PEEK), polyphenylene sulfide (PPS) or polyetherimide (PEI).

As shown in FIG. 2a, one of the thermoplastic sheets 3a may comprise at least one recess 4, with the other thermoplastic sheet 3b being flat. In this way, the conducting elements 2 may be received in the recess 4 such that it is enclosed between the recess 4 and the second thermoplastic sheet 3b.

As shown in FIG. 2b, both of the thermoplastic sheets 3,3b may comprise recesses 4, such that each conducting element 2 is disposed in a recess 4 of each thermoplastic sheet 3a,3b and is retained in the panel 1.

As shown in FIGS. 2a and 2b, the conducting elements 2 may have a circular cross-sectional shape or another shape, for example a rectangular cross-sectional shape, as shown. It will be appreciated that the conducting elements 2 may be any constant or non-constant shape as they extend through the sheet 1. The recess(es) 4 may be configured to match the shape of the conducting elements 2. For example, as shown in FIGS. 2a and 2b, a round conducting element 2 may be provided with one or two semi-circular recesses 4. Alternatively, the recess(es) 4 may be any shape suitable to receive a conducting element 2.

In another example, the conducting elements may be printed onto a surface of one sheet of thermoplastic, for example within a recess, in the manner of a printed circuit board. Then a second sheet of thermoplastic can be placed over the conducting elements and attached or bonded to the first sheet, thereby enclosing and embedding the conducting elements within the sheets.

In another embodiment, conducting elements may be integrated within a sheet by adhering the conducting elements to a surface of a sheet and then covering them with an insulating material, such as a hard-setting resin.

As shown in FIG. 3, the electrical conducting elements 2 embedded within the sheet 1 may be provided with electrical terminals 5a,5b that are joined with the conducting elements 2 and extend from an end or a side of the sheet 1 so that an electrical connector can be joined to the conducting element 2. Therefore, a power source, heater, actuator or any other apparatus may be removably connected to one of these terminals 5a,5b. Alternatively, the terminals 5a,5b may be connected to cables or wires that extend through the structure when the structure is not suited for a sheet 1 and the conducting elements 2 must take an alternative route. For example, where the conducting elements 2 must be routed through an opening in a structural member and the sheet 1 is not suitable.

The terminals 5a,5b may extend from any side of the sheet 1 and may comprise a male electrical terminal part 5a or a female electrical terminal part 5b. A female electrical terminal part 5b may be embedded in an edge or side of the sheet 1 so that an external male connector can be inserted into the embedded female connector 5b. The electrical terminals 5a,5b may comprise any standard electrical connector or may simply comprise an extension of the conducting element 2 to which a wire or cable can be attached, for example by soldering or by using a fastener.

The conducting elements 2 that are embedded within the sheet 1 may be made from copper or aluminium. These conducting elements 2 may be uncovered wires or cables that are embedded within the sheet 1, or they may include an insulating layer which is also embedded within the sheet 1. However, it will be appreciated that the sheet 1 itself may provide sufficient insulation and protection for the conducting elements 2, so that individual cable insulation is not required. It will also be appreciated that the conducting elements 2 may be made from any electrically conductive material.

Alternatively, the conducting elements 2 may be made from graphene. The graphene may be formed into wires or flat sheets that are embedded into and extend through the sheet in a similar manner to as described above. Alternatively, graphene may be combined with and integrated into a composite material, for example by combining graphene with the polymer element of a fibre reinforced polymer material, to provide a conductive path through a composite sheet. The fibre reinforced polymer material may be a carbon fibre reinforced polymer or a glass fibre reinforced polymer. The graphene may be added to the polymer element of the composite panel during laying up of the composite panel, or during the curing process. In this way, the graphene will be integrated within the sheet during manufacture of the sheet.

In another example, a metallic conducting element may be integrated into a fibre reinforced sheet in the same way as the graphene conducting elements described above.

It is important that the sheet 1 within which the conducting elements 2 are embedded provides sufficient insulation to avoid arcing of electrical power from the conducting elements 2 to any nearby surfaces. As shown in FIG. 2b, the thickness D1 of the sheet and the distance D2 between each conducting element 2 and any external surface 6a,6b of the sheet 1 should be selected to provide sufficient electrical insulation based on the operating conditions. Moreover, the thickness D1 of the sheet 1 must be sufficient to maintain shape and integrity under operating conditions. Operating conditions may include heating and/or loading and/or vibrations. The conducting elements 2 will generate some heat due to electrical resistance in the conducting elements 2 and the sheet 1 may be disposed close to other heat emitting apparatus. The sheet 1 is attached to a structural element so may be subjected to bending, torsion, vibrations and any other effects of the operating conditions.

Furthermore, as shown in FIG. 2b, the conducting elements 2 are spaced by a distance D3 within the sheet 1 to prevent any flow of electrical charge between the conducting elements 2. The required spacing D3 can be determined by considering the voltage and current being carried by the conducting elements 2 as well as the electrical insulation properties of the thermoplastic or composite material of the sheets 3a,3b.

The sheet 1 with embedded or integrated electrical conducting elements 2, as described above, may be attached to the structure of an aircraft in any way. For example, the sheet 1 may be attached to an internal surface of a panel that forms the skin of the wing of an aircraft. However, it will be appreciated that the sheet 1 may be attached to any surface of the aircraft, be it internal or external, or may be attached to other structural elements of an aircraft, for example a rib, strut or other frame member. Multiple sheets 1 can be connected together and attached to the aircraft in an adjacent manner, allowing embedded electrical conducting elements 2 to extend any distance through the aircraft, within the sheets 1. The sheet 1 can be any size or shape and the conducting elements 2 can be arranged in any configuration within the sheet 1.

The sheet 1 with integrated electrical conducting elements 2, as described above, may be attached to a surface or other structural element of the aircraft by means of adhesive, fasteners or any other means of attachment. Alternatively, if the surface or other structural element to which the sheet 1 is to be attached comprises a composite material, such as carbon fibre reinforced polymer or glass fibre reinforced polymer, the sheet 1 with the conducting elements 2 may be integrally formed with the composite surface at the curing stage of manufacturing the composite structural element. In this way, the conducting elements 2 are integrally formed within that composite structural member.

The conducting elements 2 embedded within the thermoplastic or composite sheet 1 may be for carrying electrical power or may be resistance heating elements that generate heat when an electrical current is passed through them. Alternatively, a sheet 1 may be provided with both power transmission and heat generating conducting elements 2. Alternatively, a sheet may be provided with any type of electrical conducting element.

A first example application of the invention relates to use of the invention for transmitting electrical power to heating elements which are positioned on a leading edge of the wing.

In this example, the sheet has embedded electrical conducting elements for transmitting power and the sheet is attached to a part of the wing. The electrical conducting elements extend in a longitudinal direction along the wing, in the direction of the leading edge, and are connected to heating elements that are attached to the leading edge skin panels of the wing. The sheet may be attached to the inside mould line of the top skin panel of the wing. As previously explained, the sheet may be adhered to the skin panel, fastened to the skin panel or integrally formed with the skin panel. The sheet with embedded conducting elements may be provided with electrical terminals such that the heating elements can be connected to the conducting elements using a cable.

The sheet, with embedded conducting elements, is arranged so that the conducting elements extend along the wing, from the fuselage towards the wing tip. In this way, at the fuselage end the relevant conducting elements can be connected to a power source, while at the other end the conducting elements can be connected to the heaters. The conducting elements within the sheet may turn within the sheet and extend towards the heating elements.

In a preferred example, the conducting elements of the sheet extend from the sheet into the heater which is disposed adjacent to the leading edge of the wing. In that way, the heater is attached to the sheet so that electrical power is distributed to the heater entirely within the sheet, with reduced need for cables in the leading edge area of the wing.

Alternatively, the conducting elements in the sheet may be connected to the heaters, which are disposed adjacent to the leading edge of the wing, by means of an electrical terminal that extends from a side of the sheet either towards the internal space of the wing or towards the leading edge or in another relevant direction. An electrical cable from the heater can then be connected to that terminal.

It will be appreciated that the embedded conducting elements for transmitting electrical power along the wing may alternatively be connected to other electrical apparatus, for example an actuator or light.

In a second example the electrical conducting elements embedded within a sheet may be resistance heating elements that emit heat when a current is passed through them. In this example, the sheet may be attached to, bonded to, or integrally formed with a structural element of the aircraft, such as an inner surface of a wing skin panel, to provide heat that prevents ice forming on the outer surface of the wing. In this case, the material of the sheet and the means of attaching the sheet to the structural element should be selected to allow heat energy to efficiently transfer from the sheet to the structural elements of the wing and the wing skin panel.

For example, the sheet may be made from a thermoplastic material and may be bonded to the structural element of the wing using a heat resistant adhesive. Furthermore, the sheet may be attached to the structural element such that maximum heat energy transfer occurs through a solid, heat conducting element so that heat transfer from the heating element to the wing skin is as efficient as possible, with as little energy as possible being dissipated into surrounding air.

In this example, a sheet may be provided with one or more electrical heating elements embedded within the sheet in the manner previously described, and the sheet may be formed to a shape that fits in the required space. In this example, the sheet is formed to match the inner mould line of the leading edge skin panel on the wing of an aircraft.

In this example, the electrical heating elements are configured to emit heat when an electric current is passed through them. The sheet is a thermoplastic panel so that heat from the embedded heating elements does not melt, burn or affect the material of the sheet in any way. The formed sheet is attached to the inside surface, the inner mould line, of the leading edge panel that forms a part of the skin of the wing. As previously explained, the shaped sheet may be bonded in place, for example using a resin or adhesive, or it may be attached in place using fasteners. Alternatively, if the leading edge skin panel is a composite material, such as carbon fibre reinforced polymer, the sheet with embedded heating elements may be integrally formed on the inner mould line by including the sheet during the laying up or curing process of making the carbon fibre reinforced polymer leading edge panel for the wing. In this case, an intermediate epoxy-based film material may be required to facilitate the bonding between the polymer of the fibre reinforced polymer skin panel and the sheet with embedded heating elements.

However, it will be appreciated that the sheet with embedded electrical conducting elements may itself be a panel for the skin of an aircraft. For example, the thermoplastic or composite sheet that includes the embedded conducting elements may be an external aircraft skin panel. In this way, the electrical system is embedded into the skin of the aircraft, which will save space within the wing and also reduce the weight of the electrical system.

In another example, a wing may be provided with one or more sheets having embedded heating elements that are attached to an inner mould line of a leading edge wing skin panel as well as at least one sheet with embedded conducting elements that are connected to the heating elements in the leading edge panel. Therefore, electrical power is carried to the heating elements along the wing in one panel and then used by the leading edge heaters to heat the surface of the wing to prevent ice formation and accumulation.

In a third example application, a sheet may comprise embedded electrical conducting elements for carrying low voltage power and/or electrical signals. That is, the sheet may include conducting elements for transmitting signals to/from sensors, controllers, actuators and other apparatus in the wing.

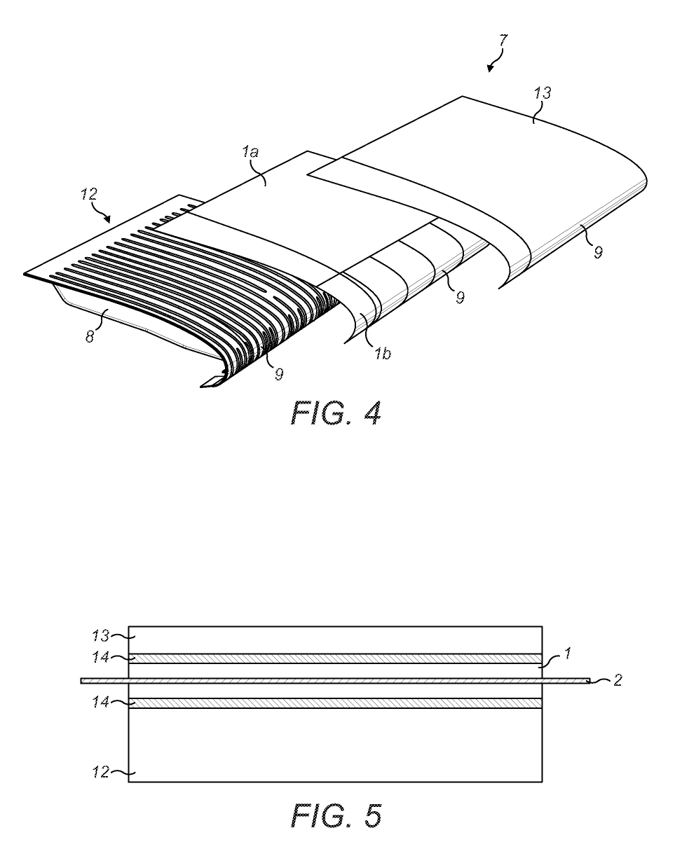

A preferred embodiment of the invention, shown in FIGS. 4 to 7, has conducting elements embedded in a sheet which is attached to the wing such that power is transmitted from the power source to the heating elements along conducting elements, wherein all of the conducting elements, including the heating elements, are embedded in the same sheet. In this way, the sheet can be attached or bonded to a panel of the aircraft wing and this panel will have the conducting elements embedded within the panel.

FIG. 4 shows a wing 7 of an aircraft, with three component layers that are separated to illustrate the construction of the wing: a support structure 12 which is connected to the rib 8; an outer skin layer 13 that protects against erosion and provides a smooth aerodynamic surface; and, an intermediate sheet 1a,1b that comprises conducting elements for carrying power and heating elements for heating the leading edge 9 of the wing 7 during flight. The intermediate sheet 1a,1b, comprising the conducting elements and heating elements, is separated into a first part 1a having conducting elements to transmit electrical power and a second part 1b having heating elements. As previously explained, the intermediate sheet 1a,1b may comprise a thermoplastic material within which the conducting elements are embedded. The power carrying conducting elements extend from the first part 1a to the second part 1b and are connected to the heating elements.

As shown, each of the layers 12, 13, 1a, 1b extends around the leading edge 9 of the wing 7. The second part 1b of the intermediate panel 1a,1b, with the embedded heating elements, is disposed around the leading edge profile of the wing. In this way, electrical power can be carried along the wing through the conducting elements in the first part 1a of the intermediate sheet 1a, 1b and into the heating elements in the second part 1b of the intermediate sheet 1a,1b.

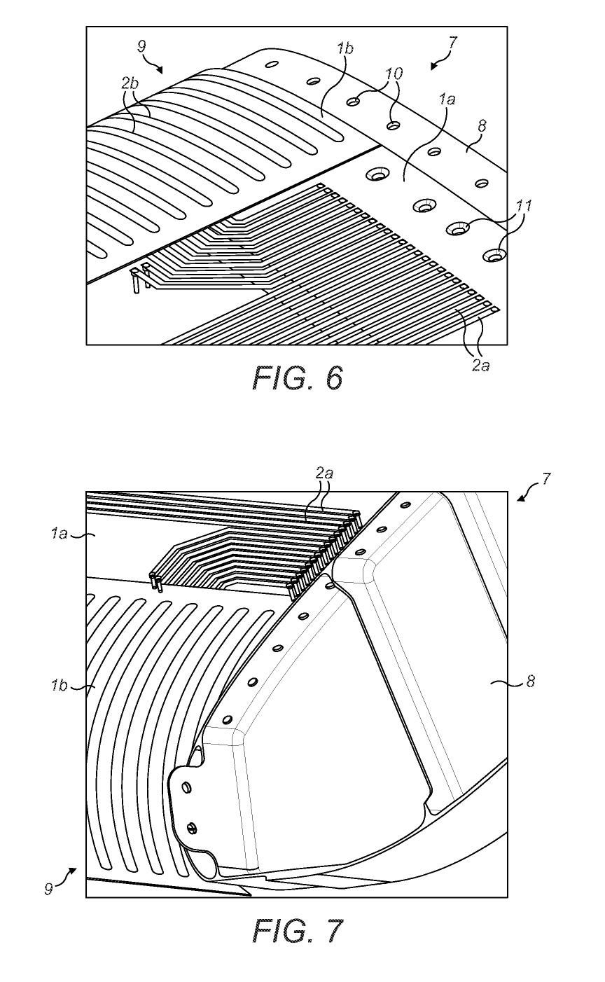

FIG. 5 shows a cross-section of a part of the wing 7 of FIG. 6. The inner support structure 12 may be made from a composite material, such as carbon fibre reinforced polymer, or may be made from a metal, such as aluminium. The intermediate sheet 1 is bonded to the support structure 12 and comprises a conducting element 2 which extends through the intermediate sheet 1. The intermediate sheet 1 is formed in any of the ways previously described with reference to FIGS. 1 to 3. The conducting element 2 may be for transmitting electrical power or it may be a heating element. The outer skin layer 13, to protect against erosion and provide a smooth aerodynamic surface, is also shown. The outer skin layer 13 may comprise a metal, such as aluminium, or a composite material such as carbon fibre reinforced polymer. In between each of the layers is a bonding layer 14. As previously explained, this may comprise an adhesive, or an adhesive film to facilitate bonding of two different materials.

FIG. 6 shows a view of a wing 7 with the external skin layer 13 (see FIG. 4) removed. A rib 8 is shown which extends across the wing 7, from the leading edge 9 to the trailing edge (not shown). The rib 8 comprises mounting holes 10 to which the external skin layer is fastened. Also shown is a sheet 1a,1b with embedded conducting elements 2a,2b that includes a first part 1a with conducting elements 2a for transmitting power, shown on the top side of the wing 7, and a second part 1b with resistive heating elements 2b for generating heat, shown extending around the leading edge 9 of the wing 7. In this example, the first part 1a of the sheet comprises a plurality of conducting elements 2a that extend in a longitudinal direction along the wing 7. Each pair of these conducting elements 2a is for providing power to a resistive heating element 2b embedded in the second part 1b of the sheet, which extends around the inside face of the leading edge 9 of the wing 7.

As shown in FIG. 6, at the appropriate position the power transmission conducting elements 2a formed in the first part 1a of the sheet 1a,1b will turn towards the leading edge 9 and extend into the second part 1b of the panel 1a,1b to connect to the embedded resistive heating elements 2b. The resistive heating elements 2b follow a path through the second part 1b of the sheet such that the outer skin layer of the leading edge 9 of the wing 7 is substantially evenly heated across its surface, to prevent ice from forming in any location on the leading edge 9.

Also shown in FIG. 6, the sheet 1a,1b may be provided with apertures 11 for mounting a part of the sheet 1a,1b to the wing structure. In this example, the apertures 11 are formed in the first part 1a of the sheet and are for attaching the sheet 1a,1b to the rib 8. However, it will be appreciated that the apertures may be for allowing a fastener to pass through the sheet and into the rib, for mounting the outer skin layer. It will be appreciated that both parts of the sheet 1a,1b may be integrally formed with, or attached to, the outer wing skin layer by any of the previously described means.

FIG. 7 shows an internal view of the wing 7 of FIG. 6, with a sheet comprising a first part 1a with conducting elements 2a for transmitting power and a second part 1b with resistive heating conducting elements 2b. As shown, the power transmitting conducting elements 2a may be provided with electrical terminals 5a,5b that extend into the interior of the wing for connecting the conducting elements to the power source, electrical apparatus, controller, or, if required, an earth. These terminals are similar to those described with reference to FIG. 3. In this example, the power transmission conducting elements 2a within the first part 1a of the sheet can be used to provide power to any electrical apparatus in the wing.

In the example described with reference to FIGS. 4 to 7, the sheet with embedded conducting elements may extend any length along the wing. For example, a different sheet may be provided between each rib extending through the wing. The conducting elements in adjacent sheets can be connected together so that power can be transmitted all the way along the wing within the sheets.

The example described with reference to FIGS. 4 to 7 above is advantageous over the conventional heater mat and cable harnesses solution because the conducting elements 2a,2b for power transmission and heat generation are embedded within the sheet 1a, 1b of the wing which may be integrated into the wing. Therefore, no space consuming cable harnesses are required and the sheet 1a,1b will provide the conducting elements 2a,2b with integral protection and insulation. The conducting elements 2a,2b are prevented from sagging or movement and are protected against vibrations. Moreover, the sheet 1a,1b provides sufficient electrical insulation to prevent arcing or short circuiting. Furthermore, the sheet 1a,1b provides protection against rubbing and wear. Maintenance is also simplified because if a conducting element 2a,2b were to fail then that sheet 1a,1b can quickly and easily be replaced, without having to dismantle the internal wing structure and disconnect a cable harness from supports within the wing.

It will be appreciated that the wing may be provided with a sheet having embedded electrical conducting elements on any surface of the wing, whether that surface is an internal surface of the skin, a surface of a structural element or an external surface of the skin or any other surface. Alternatively, a sheet may be attached to a structural element of the wing such that the sheet itself forms a surface. The sheet may be a part of the skin panels of the aircraft, for example an external skin panel for the wing or fuselage.

It will be appreciated that, as previously described, the first part 1a and second part 1b of the sheet described with reference to FIGS. 4 to 7 may be formed from two separate sheets, with electrical connectors used to connect the terminals of the first sheet to the terminals of the other panel, as required.

In the above described examples of a sheet, having either power transmission conducting elements and/or resistive conducting elements for generating heat embedded within the sheet, the conducting elements should be configured to be able to carry a sufficient amount of electrical power. In particular, the size of the conducting elements and the selected material should be suitable for the relevant application. In one example, where the conducting elements carry electrical power for resistive heating elements in the wing, 150 kW may be required per wing, at a voltage of between 500 Volts and 5000 Volts. However, other electrical applications on an aircraft are much lower power and voltages typically range from 28 Volts DC to 540 Volts DC or 115 Volts AC to 230 AC. Therefore, it will be appreciated that the invention is not limited to any particular range of electrical power or voltage and that the size and separation of the conducting elements, and the thickness of the sheet or panel, should be selected according to the electrical power being conducted by the conducting elements.

In another example, a sheet is provided with electrical conducting elements that are configured to carry low voltage power and/or electrical signals. These sheets with embedded conducting elements may be used to connect sensors and other low power apparatus, such as for example lights, to a power source and/or a controller. In this case, the low electrical power means that the conducting elements can be smaller and less separation between the conducting elements is required. However, signal carrying conducting elements may require protection from electrical interference and, in this case, the conducting elements may be provided with a protective sheath within the panel and/or on an outside surface of the sheet.

It will be appreciated that a panel may be provided with multiple conducting elements configured for any application—power supply, heat generation, signal carrying or any other electrical application.

In any of the previously described examples where the sheets are used to provide electrical power and/or signals to heating elements on the leading edge of an aircraft wing, the heat generated by those heating elements will act to prevent ice formation and accumulation in surrounding areas. Furthermore, as the conducting elements are embedded within a rigid and insulating sheet, the conducting elements are protected from arcing and shorting. Furthermore, there is a reduced likelihood of the cables or insulation being broken or damaged by vibrations, rubbing, chafing or bending and flexing. The conducting elements are embedded within and protected by the sheet themselves.

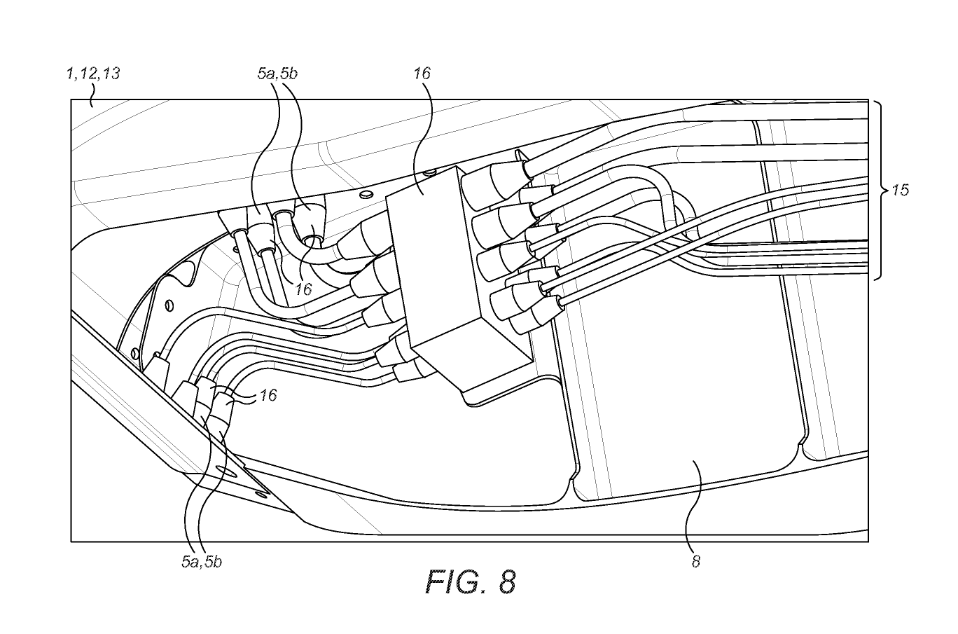

Moreover, because the conducting elements are embedded within the sheet which is disposed against a surface of the wing there is no need for cable harnesses to extend along the wing. Therefore, less of the space within the wing is occupied by cables, wires, brackets, insulation and other electrical apparatus. As shown in FIG. 8, a single electrical harness 15 can be connected, optionally via a junction box 16 as shown, to the panels 1, 12, 13 of the wing 7. Thereafter, electrical power and/or signals are transmitted along the wing 7, from the base of the wing near to the fuselage to the wing tip, via the conducting elements embedded in the wing panels 1. The cable harness 15 arrangement shown in FIG. 8 is disposed adjacent to the closing rib 8, which is positioned at the base of the wing.

As shown in FIG. 8, the cables of the cable harness 15 connect to the conducting elements within the wing panels 1, 12, 13 via terminals 5a, 5b and connectors 16 that extend from the panel 1, 12, 13, as previously explained with reference to FIG. 3. In this way, the cable harnesses 15 do not extend longitudinally along the wing 7, which creates additional space for the other services being routed along the wing 7, such as a mechanical driveshaft and any pneumatic equipment or any other electrical cable harness that may not be suitable for conducting elements that are embedded within the panels of the wing.

In the leading edge heating example, the sheets are provided with several conducting elements so that power is circulated from the power source, along the conducting elements in the sheets, through the heating elements in the leading edge and back to the fuselage. The electrical circuit for each of the heating elements in the leading edge may have a separate pair of conducting elements within the sheet. Therefore, each conductive path is separate to any other. In this way, if one conducting element or one heating element fails then only that heating element will not produce the desired heat. On the other hand, if the heating elements shared a power supply conducting element, then failure of that conducting element would result in more heating elements failing.

In one example, the electrical system, which includes the conducting elements in the sheets and any other connected apparatus, may include a controller. The controller may be configured to independently control the power and/or signals being carried along the conducting elements in the sheets and may additionally monitor the power and/or signals. In the previously described example of leading edge heating elements, the electrical system may include temperature sensors disposed to detect the temperature of each heating element, or the temperature of the surface, and convey this information to the controller. In this way, the controller is able to monitor the performance of the heating elements and make any necessary adjustments to the performance of the heating elements. For example, the controller is able to prevent overheating of the skin panels or other parts of the aircraft and is also able to react to any faults. For example, if a conducting element were to fail during operation then the corresponding heating element would not generate heat and the corresponding area of the wing will not be heated, leaving it vulnerable to ice formation. However, the controller may identify this problem and increase the power being supplied to an adjacent heating element, via the relevant conducting element, so that the risk of ice formation is reduced.

The invention as defined in the claims has the advantages that, wherever the sheets with embedded conducting elements are used and for whatever purpose, the weight of the electrical system is reduced. This is due to the cooling advantages realised by having the conducting elements embedded in a panel and not bundled together in a harness, meaning that the conducting elements themselves can be smaller. Also, by embedding the conducting elements in a panel, fewer ancillary components, such as brackets and harnesses, are required which will reduce the weight of the system. Moreover, the space occupied by the conducting elements of the invention is significantly less than the space occupied by a system of cable harnesses and associated components.

Furthermore, the sheets with embedded conducting elements greatly simplify the maintenance and servicing of the electrical system. For example, if a conducting element were to fail or need to be replaced for some other reason then this can be achieved simply by replacing the relevant sheets or panels with attached sheets. This can be achieved quickly and simply and without having to dismantle large internal assemblies, such as actuators and slats. Further, the maintenance operations of any apparatus which is in the vicinity of the sheets is also simplified because there are no longer any cable harnesses, brackets and other parts in the space surrounding that apparatus.

Another advantage of using the panels with integrated sheets and conducting elements on an aircraft is that the sheets may overcome the requirements of having to segregate electrical systems from other apparatus and other electrical systems. This is due to the risk of the wires or cables becoming exposed or short circuited. However, when the conducting elements are embedded in the sheets the risk is greatly reduced and so the sheets or panels can themselves be used to segregate different areas.

Another advantage of the invention as defined in the claims is realised when the panels of the invention, which include the sheets with integrated conducting elements, are used to carry electrical power and/or signals and are disposed on or close to the outer skin of an aircraft, as described with reference to FIGS. 4 and 5. The outer skin panel of an aircraft will be relatively cold because heat is dissipated into the cold air flowing over the wing. Therefore, the conducting elements in the panels will also be cooled. This will reduce resistance in the conducting elements and improve the quality of any signals being carried. Moreover, as the resistance in the conducting elements will be reduced, the size of the conducting elements themselves can be reduced while still carrying the same current. Therefore, the size of the conducting elements can be reduced which will further reduce the size and weight of the electrical system. This is advantageous over cable harnesses disposed within the wing because bundles of cables in harnesses, disposed away from the surface of the wing, will not be cooled and the cables themselves have to be larger to cope with the additional heat being generated by the conducting elements. This increases the weight of the system and space it occupies.

It will be appreciated that the invention as defined in the claims is not limited to providing power for heating elements and is not limited to use in an aircraft. On the contrary, the invention defined in the claims may be applied anywhere within an aircraft and the sheets or panels may be used to transmit power and/or signals to any electrical equipment.

1. A panel to form part of an external skin of an aircraft, comprising a body having a plurality of integral conductors for the transmission of electrical power and/or signals through said body to heating elements and/or other apparatus connected to said integral conductors, said integral conductors being embedded in said body and insulated from each other.

2. The panel of claim 1, wherein said body is formed from a thermoplastic material.

3. The panel of claim 2, wherein the body comprises thermoplastic layers, the conductors being sandwiched between said thermoplastic layers to form an insulated sheet.

4. The panel of claim 1, wherein said body is formed from a fibre reinforced polymer material.

5. The panel of claim 4, wherein the body comprises fibre reinforced polymer layers, the conductors being sandwiched between said fibre reinforced polymer layers to form an insulated sheet.

6. The panel of claim 5, wherein the insulated sheet is an integral part of the panel.

7. The panel of claim 3, wherein said insulated sheet is bonded or attached to a surface of said panel during manufacture of said panel.

8. The panel of claim 1, further comprising a terminal that is connected to each conductor to facilitate connection of electrical apparatus to each conductor.

9. The panel of claim 8, wherein the panel comprises at least one first conductor configured to transmit electrical power to a resistive electric heating element.

10. A method of manufacturing a panel to form part of an external skin of an aircraft, said panel comprising a body and the method including the step of integrating a plurality of conductors into said body for the transmission of electrical power and/or signals through said body to heating elements and/or other apparatus connected to said integral conductors by embedding said conductors into said body so that they are insulated from each other.

11. The method of claim 10, further comprising the step of positioning said conductors between thermoplastic layers to form an insulating sheet and embedding said sheet into the panel during the step of manufacturing the panel.

12. The method of claim 10, further comprising the step of integrating said conductors within a fibre reinforced polymer material.

13. The method of claim 12, wherein the fibre reinforced polymer material forms an integral part of the panel and the step of integrating said conductor with a fibre reinforced polymer material comprises embedding said conductors into said fibre reinforced polymer material during the step of laying up or curing said fibre reinforced polymer material to form the panel.
